(19) United States
(12) Patent Application Publication
(10) Pub. No.: US 2010/0059111 A1
(43) Pub. Date: Mar. 11, 2010

(54) Solar Cell Module having Multiple Module Layers and Manufacturing Method Thereof

(76) Inventors: Myung-Hun Shin, Suwon-si (KR); Czang-Ho Lee, Suwon-si (KR); Min-Seok Oh, Yongin-si (KR); Ku-Hyun Kang, Suwon-si (KR); Yuk-Hyun Nam, Goyang-si (KR); Seung-Jae Jung, Seoul (KR); Min Park, Seoul (KR); Mi-Hwa Lim, Seocheon-gun (KR); Joon-Young Seo, Seoul (KR)

Correspondence Address: Haynes and Boone, LLP;IP Section, 2323 Victory Avenue, SUITE 700, Dallas, TX, 75219, US

(21) Appl. No.: 12/412,606

(22) Filed: Mar. 27, 2009

(30) Foreign Application Priority Data
Sep. 5, 2008 (KR) 10-2008-0087588

(51) Int. Cl. H01L 31/0216; H01L 21/02

(52) U.S. Cl. 136/256; 438/72; 438/73; 257/E21.002

(57) ABSTRACT

A solar cell module includes a bottom module layer formed on a first substrate and absorbing a greater fraction of light energy in a first wavelength band than in a second wavelength band. The first wavelength band includes a shorter wavelength than any wavelength in the second wavelength band. A top module layer is formed on the bottom module layer to absorb a greater fraction of light energy in the second wavelength band than in the first wavelength band. A second substrate is formed on the top module layer. A reflecting filter is provided between the bottom module layer and the top module layer. The reflecting filter reflects a greater fraction of light energy in the first wavelength band than in the second wavelength band and transmits a greater fraction of light energy in the second wavelength band than in the first wavelength band.

### CROSS-REFERENCE TO RELATED APPLICATION

This application claims priority to and the benefit of Korean Patent Application No. 10-2008-0087588 filed in the Korean Intellectual Property Office on Sep. 5, 2008, the entire contents of which are incorporated herein by reference.

### BACKGROUND OF THE INVENTION

(a) Field of the Invention

The present invention relates to a solar cell module having multiple module layers.

(b) Description of the Related Art

Some solar cells use two kinds of semiconductor materials (P-type and N-type) to convert solar energy into electrical energy.

The solar cell has been spotlighted as a next-generation, clean energy source that can replace fossil fuel sources and atomic energy sources. Fossil fuel sources undesirably produce a greenhouse effect due to CO₂ discharge. Atomic energy sources pollute the environment (including air) by radioactive waste.

In order to put the solar cell to practical use, a need exists for reducing manufacturing costs and increasing the cell's energy conversion efficiency. Variables that determine the efficiency of a solar cell may include open circuit voltage (Voc), short circuit current (Isc), fill factor (FF), and the like.

The spectrum of sunlight has a peak in the vicinity of 600 nm, and has a wide wavelength range from ultraviolet to far infrared. In order to absorb the greatest possible range of wavelengths, it is preferable to use semiconductor materials with small bandgap energy. However, as the bandgap energy becomes smaller, the open circuit voltage Voc decreases. Therefore, materials with some optimal bandgap are needed.

In a solar cell that depends on a single energy bandgap, the absorbable spectrum has a limited range, which places a limit on the photoelectric conversion efficiency. Therefore, it is desirable to develop a stacked solar cell module with multiple energy bandgaps to perform separate, efficient photoelectric conversion for different wavelength bands present in the sunlight.

The above information disclosed in this Background section is only for enhancement of understanding of the background of the invention and therefore may contain information that does not form prior art for this invention.

### SUMMARY

This section describes some features of the invention. Other features are described in subsequent sections. The invention is defined by the appended claims.

The present invention has been made in an effort to provide an improved solar cell module having multiple module layers.

Some embodiments provide various advantages, e.g. voltage matching of different module layers to reduce energy losses when the module layers are interconnected in parallel.

Some embodiments of the present invention provide a solar cell module comprising: a first substrate; a bottom module layer formed on the first substrate and absorbing a greater fraction of light energy in a first wavelength band than in a second wavelength band, the first wavelength band comprising a shorter wavelength than any wavelength in the second wavelength band; a top module layer formed on the bottom module layer and absorbing a greater fraction of light energy in the second wavelength band than in the first wavelength band; a second substrate formed on the top module layer; and a reflecting filter between the bottom module layer and the top module layer, wherein the bottom module layer and the top module layer are bonded to each other by a polyethylene vinyl acetate (EVA) sheet disposed between the bottom module layer and the top module layer, wherein the reflecting filter reflects a greater fraction of light energy in the first wavelength band than in the second wavelength band and transmitting a greater fraction of light energy in the second wavelength band than in the first wavelength band, wherein the bottom module layer and the top module layer each include a plurality of unit cells that are serially connected to each other.

In some embodiments, the bottom module layer comprises: a first transparent conductive film formed on the first substrate; a first semiconductor layer comprising: (i) a first P layer disposed on the first transparent conductive film, (ii) an I layer formed of intrinsic amorphous silicon and disposed on the first P layer, and (iii) a first N layer disposed on the first P layer; and a transparent electrode disposed on the first semiconductor layer. The top module layer comprises: a reflecting electrode film disposed on the second substrate; a second semiconductor layer comprising: (i) a second P layer disposed on the reflecting electrode film, and (ii) a second N layer disposed on the second P layer; and a second transparent conductive film underlying the second semiconductor layer, wherein the bottom module layer and the top module layer are bonded to each other by a polyethylene vinyl acetate (EVA) sheet disposed between the transparent electrode and the second transparent conductive film.

In some embodiments, the second P layer is formed of CuInSe₂ (CIS) or CuInGaSe₂ (CIGS), and the second N layer is formed of CdS.

In some embodiments, the reflecting electrode film is formed of one of aluminum (Al), copper (Cu), and molybdenum (Mo).

In some embodiments, the transparent electrode is formed of one of SnO₂, ZnO:Al, and ZnO:B.

In some embodiments, the reflecting filter is formed of a material based on an inorganic oxide film.

In some embodiments, the reflecting filter is formed of TiO₂ or SiNx.

In some embodiments, the bottom module layer and the top module layer each include output electrodes that are connected to one or more external devices, the output electrodes of the top module layer not being directly connected to the output electrodes of the bottom module layer.

In some embodiments, the bottom module layer is connected in parallel to the top module layer, and

0.6≦(N1/N2)≦0.8

where N1 is the number of cells that are serially connected to each other in the bottom module layer and N2 is the number of cells that are serially connected to each other in the top module layer.

Some embodiments, further comprise a Schottky diode connected between an output electrode of the bottom module layer at least one external device, and comprising a Schottky diode connected between an output electrode of the top module layer at least one external device.

Some embodiments provide a method for manufacturing a solar cell module comprising a bottom module layer for absorbing a greater fraction of light energy in a first wavelength band than in a second wavelength band, the first wavelength band comprising a shorter wavelength than any wavelength in the second wavelength band, the solar cell module also comprising a top module layer formed on the bottom module layer and absorbing a greater fraction of light energy in the second wavelength band than in the first wavelength band, the method comprising: forming the bottom module layer on a first substrate, the bottom module layer comprising a plurality of cells serially connected to each other; forming a reflecting filter over the bottom module layer, the reflecting filter reflecting a greater fraction of light energy in the first wavelength band than in the second wavelength band and transmitting a greater fraction of light energy in the second wavelength band than in the first wavelength band; forming the top module layer on a second substrate, the top module layer comprising a plurality of cells serially connected to each other; and after forming the bottom module layer and the top module layer, bonding the bottom module layer and the top module layer together by using an EVA sheet.

In some embodiments, forming the bottom module layer comprises: depositing a first transparent conductive film on the first substrate; patterning the first transparent conductive film; after patterning the first transparent conductive film, forming a first semiconductor layer over the first transparent conductive film, the first semiconductor layer comprising a first P layer, an I layer of amorphous silicon overlying the first P layer, and a first N layer overlying the I layer; patterning the first semiconductor layer; after patterning the first semiconductor layer, forming a transparent electrode over the first semiconductor layer; and after forming the transparent electrode, patterning the transparent electrode and the first semiconductor layer.

Some embodiments further comprise texturing an upper surface of the first transparent conductive film.

In some embodiments, forming the top module layer comprises: forming a reflecting electrode film on the second substrate; patterning the reflecting electrode film; after patterning the reflecting electrode film, forming a second semiconductor layer over the reflecting electrode film, the second semiconductor layer comprising a stack of a second P layer formed of CuInSe₂ or CuInGaSe (CIGS) and a second N layer; patterning the second semiconductor layer; after patterning the second semiconductor layer, forming a second transparent conductive film over the second semiconductor layer; and then patterning the second transparent conductive film and the second semiconductor layer.

Some embodiments further comprise texturing the upper surface of the reflecting electrode film after forming the reflecting electrode film.

The invention is defined by the appended claims.

### BRIEF DESCRIPTION OF THE DRAWINGS

FIG. 1 is a cross-sectional view showing a solar cell module having multiple module layers according to an exemplary embodiment of the present invention.

FIG. 2 to FIG. 6 are cross-sectional views showing a bottom module layer of the solar cell module of FIG. 1 at different stages of fabrication.

FIG. 7 is a cross-sectional view showing details of a top module layer of the solar cell module of FIG. 1.

FIG. 8 is a perspective view showing a solar cell module with multiple module layers according to an exemplary embodiment of the present invention.

FIG. 9 is a perspective view showing a circuit connection in a solar cell module with multiple module layers according to an exemplary embodiment of the present invention.

### DESCRIPTION OF SOME REFERENCE NUMERALS USED IN THE DRAWINGS

100, 200: SUBSTRATE
110: FIRST TRANSPARENT CONDUCTIVE FILM
120, 130, 140: P LAYER, I LAYER, N LAYER
150: TRANSPARENT ELECTRODE
160: REFLECTING FILTER 170: EVA SHEET
210: REFLECTING ELECTRODE FILM
220, 230: P LAYER, N LAYER
240: SECOND TRANSPARENT CONDUCTIVE FILM
B, T: BOTTOM MODULE LAYER, TOP MODULE LAYER
S1, S2: OUTPUT SIGNAL LINE D: SCHOTTKY DIODE

### DETAILED DESCRIPTION OF SOME EMBODIMENTS

Exemplary embodiments of the present invention will now be described in detail with reference to the accompanying drawings. However, the present invention is not limited to these embodiments.

In the drawings, the thicknesses of layers and regions can be exaggerated for clarity. It is to be noted that when a layer is referred to as being “on” another layer or substrate, then intermediate layers may or may not be present.

Like constituent elements are denoted by like reference numerals throughout the specification.

FIG. 1 is a cross-sectional view showing a solar cell module with multiple module layers according to an exemplary embodiment of the present invention. The solar cell module of FIG. 1 includes a first transparent conductive film 110 stacked on a first substrate 100. The first transparent conductive film 110 may be formed of one or more of SnO₂, ZnO:Al, ZnO:B, and the like. The upper surface of the transparent conductive film 110 may be textured so as to reduce reflection from the solar cell module and to correspondingly increase absorption of valid light by the solar cell module. The texture can be etched in the upper surface of the first transparent conductive film 110 and can be a pyramid structure sized to within 10 μm.

In solar cells operating based on diffusion of electron-hole pairs generated by sunlight, the diffusion length of electron-hole pairs is very short in cells of thin film type compared to crystalline silicon PN junction type. Therefore, a thin film cell may be provided with a light absorbing layer of intrinsic silicon between the cell's P layer and the cell's N layer. Intrinsic silicon generates an internal electric field at the junctions with the P and N layers. The intrinsic silicon layer is shown as I layer 130 in FIG. 1. The I layer 130 is inserted between a P layer 120 and an N layer 140 which are stacked on the first transparent conductive layer 110. The P layer 120, the I layer 130, and the N layer 140 can be deposited by plasma enhanced chemical vapor deposition (PECVD).

When electron-hole pairs are generated by sunlight in the light-absorbing I layer 130, the internal electric field generates current by causing the electrons to drift to, and be collected in, the N layer 140 and by causing the holes to drift to, and be collected in, the P layer 120.

The P layer 120 may be formed of boron doped amorphous silicon (a-Si), boron doped amorphous silicon carbide (a-SiC), or boron doped microcrystalline silicon (mc-Si). The I layer 130 and the N layer 140 serve as light absorbing layers and may be formed respectively of intrinsic and N doped amorphous silicon (a-Si).

A transparent electrode 150 is formed on the N layer 140, possibly of one or more of SnO₂, ZnO:Al, ZnO:B, and the like. The first transparent conductive film 110, the P layer 120, the I layer 130, the N layer 140, and the transparent electrode 150 form a bottom module layer B. The solar cell module includes one or more additional module layers. Sunlight enters the solar cell module through the bottom module layer B. The bottom module layer B mainly absorbs short wavelengths.

A reflecting filter 160 is formed on the transparent electrode 150. The reflecting filter 160 selectively reflects the short wavelengths, making it possible to increase absorption efficiency of the short wavelengths in the bottom module layer B. The reflecting filter 160 can be a reflecting film based on an inorganic oxide. For example, the reflecting filter 160 may be formed of TiO₂. Alternatively, the reflecting filter 160 may include, or consist essentially of, SiNx or an inorganic polymer.

An EVA sheet 170 is formed on the reflecting filter 160. The EVA sheet 170 is a vinal film which is a copolymer of ethylene. This material is excellent as regards transparency, buffer property, elasticity, and tensile strength. In the solar cell module being described, the EVA sheet 170 is used to bond the bottom module layer B to the top module layer T.

A second transparent conductive film 240 is formed on the EVA sheet 170. The second transparent conductive film 240 is formed of one or more of SnO₂, ZnO:Al, ZnO:B, and the like. An N layer 230 and a P layer 220 are sequentially formed on the second transparent conductive film 240. The N layer 230 is formed of CdS. The P layer 220 is formed of CuInSe₂ (CIS) or CuInGaSe₂ (CIGS) and serves as a light absorbing layer. CIS provides a large short circuit current Jsc and a low open circuit voltage Voc because CIS has a small bandgap as compared to other light absorbing materials used in solar cells. Therefore, in order to increase the open circuit voltage Voc, elements such as Ga may be added, to form CIGS for example.

A reflecting electrode film 210 is formed on the P layer 220. The reflecting electrode film 210 may be formed of any one or more of aluminum (Al), copper (Cu), and molybdenum (Mo). A second substrate 200 is formed on the reflecting electrode film 210.

The reflecting electrode film 210, the P layer 220, the N layer 230, and the second transparent conductive film 240 form the top module layer T. The top module layer T absorbs the long wavelengths that pass through the bottom module layer B.

In summary, in the solar cell module of FIG. 1, the bottom module layer B is bonded to the top module layer T by means of the EVA sheet 170. The bottom module layer B and the top module layer T absorb light in different wavelength bands. The reflecting filter 160 on the bottom module layer B selectively reflects the short wavelengths to increase the light absorption in the bottom module layer B.

The light absorbing layers in the bottom module layer B consist essentially of materials suitable to absorb the short wavelengths. These materials absorb essentially only the short wavelengths. The light absorbing layers in the top module layer T consist essentially of materials suitable to absorb the long wavelengths. These materials absorb essentially only the long wavelengths. Consequently, high efficiency is achieved.

A solar cell module may contain a number of bottom cells below the EVA sheet 170 and a number of top cells above the EVA sheet 170. Each bottom cell has the structure of the bottom module layer B of FIG. 1. The bottom cells can be serially connected to each other, and will be referred to as the bottom module layer B of the solar cell module. Each top cell has the structure of the top module layer T of FIG. 1. The top cells can be serially connected to each other, and will be referred to as the top module layer T of the solar cell module.

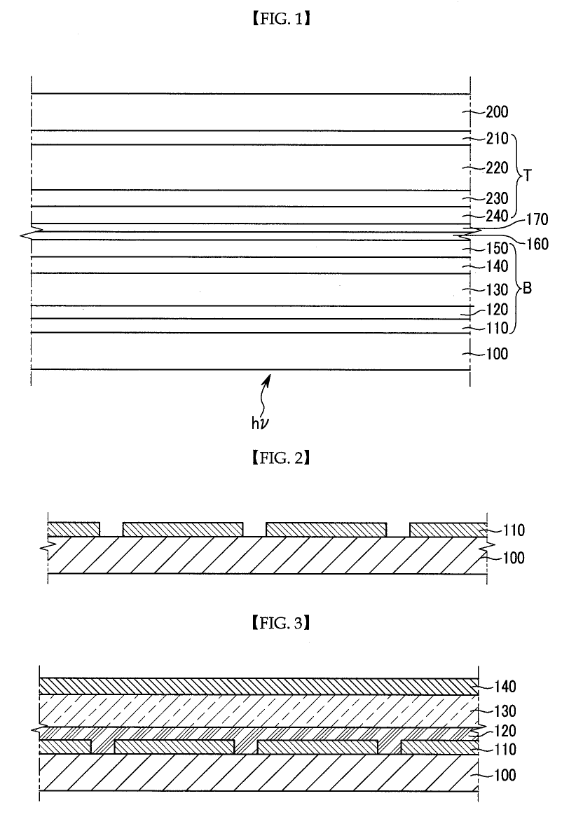

FIG. 2 to FIG. 6 are cross-sectional views illustrating a method of fabricating the bottom module layer B for such a solar cell module.

First, as shown in FIG. 2, the first transparent conductive film 110 is deposited on the first substrate 100 and then patterned by laser scribing. Prior to patterning, a texture of protrusions and depressions can be etched in the upper surface of the first transparent conductive film 110 to help scatter light incident on the first substrate 100.

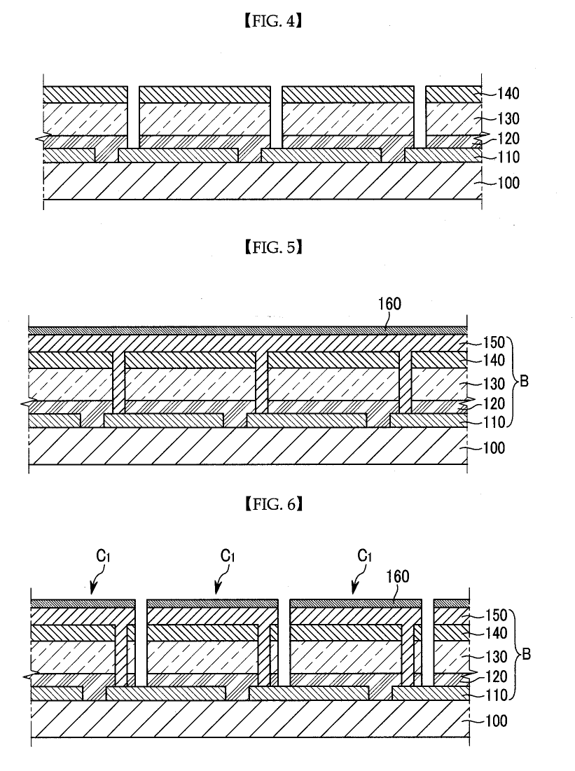

Next, as shown in FIG. 3, a first semiconductor layer is formed over the first transparent conductive film 110 by depositing the P layer 120, then the I layer 130, and then the N layer 140. The P layer 120, the I layer 130, and the N layer 140 can be deposited by plasma enhanced chemical vapor deposition (PECVD).

Subsequently, as shown in FIG. 4, the first semiconductor layer (i.e. the stack of P layer 120, I layer 130, and N layer 140) is patterned by laser scribing.

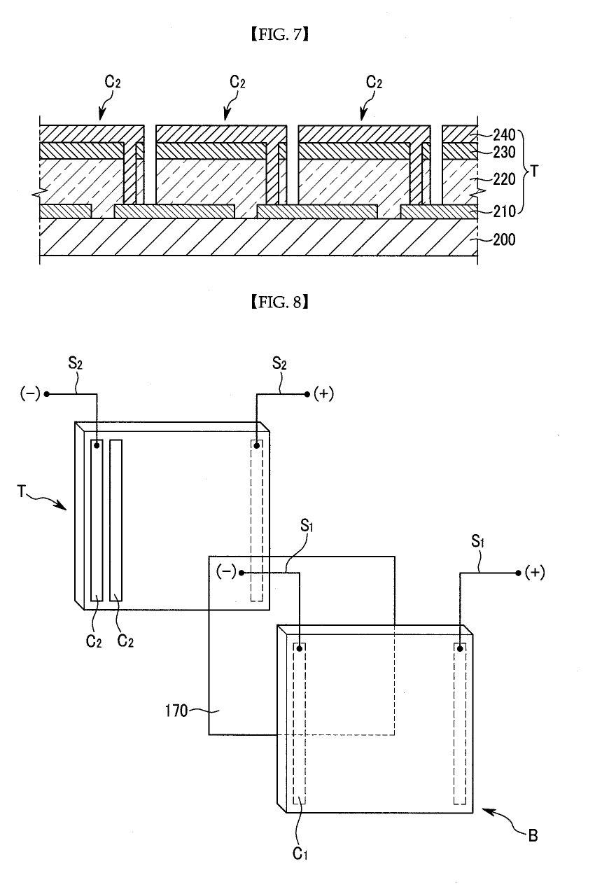

Thereafter, as shown in FIG. 5, the transparent electrode 150 is deposited over the first semiconductor layer, and is coated with the reflecting filter 160 which selectively reflects the short wavelengths. The transparent electrode 150 may be formed of SnO₂, ZnO:Al, or ZnO:B. The reflecting filter 160 is a reflecting film which may include, or consist mostly or essentially of, an inorganic oxide (for example, TiO₂), or SiNx, or an inorganic polymer. The reflecting filter 160 can be deposited by chemical vapor deposition, sputtering, evaporation, or other techniques.

Next, as shown in FIG. 6, the transparent electrode 150 and the first semiconductor layer are patterned by laser scribing into a plurality of cells C1 which are the bottom cells of the solar cell module and which together form the bottom layer B of the solar cell module. The cells C1 are serially connected to each other. FIG. 1 shows one cell C1 of FIG. 6.

The number of cells C1 and the spacing between the cells C1 are determined by the fabrication process and in particular by the patterning steps.

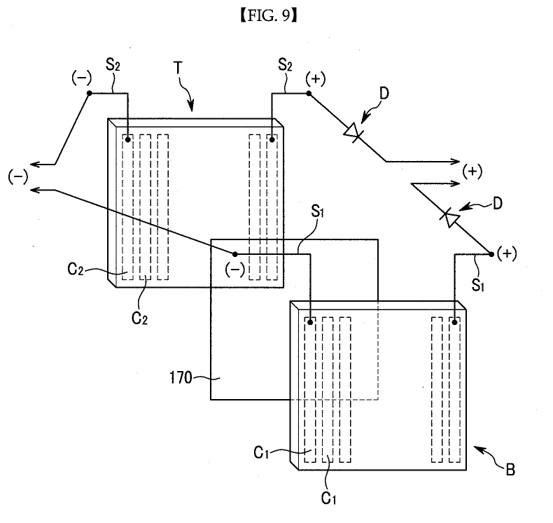

FIG. 7 is a cross-sectional view showing a method of forming the top module layer T of the solar cell module of FIG. 1.

First, as shown in FIG. 7, the reflecting electrode film 210 is formed on the second substrate 200 and is patterned by laser scribing. Prior to patterning, a texture of protrusions and depressions can be etched in the upper surface of the first transparent conductive film 210 to help reflect light emerging from the bottom module layer B, making it possible to increase the light efficiency. The reflecting electrode film 210 may be formed of aluminum (Al), copper (Cu), or molybdenum (Mo).

Next, a second semiconductor layer is formed on the reflecting electrode film 210 by depositing the P layer 230 and then the N layer 240. The P layer 220 and the N layer 230 may be deposited by plasma enhanced chemical vapor deposition (PECVD). The P layer 220 is formed of CuInSe₂ (CIS) or CuInGaSe₂ (CIGS) and is used as a light absorbing layer. The N layer 230 is formed of CdS. The P layer 220 has a bandgap of 1.2 eV to 1.45 eV.

Next, the second semiconductor layer (i.e. the stack of P layer 220 and N layer 230) is patterned by laser scribing.

Thereafter, the transparent electrode film 240 is deposited over the second semiconductor layer. The second transparent conductive film 240 and the second semiconductor layer are then patterned by laser scribing into a plurality of cells C2 which are the top cells of the solar cell module and which form the top module layer T of the solar cell module. The cells C2 are serially connected to each other.

The number of cells C2 and the spacing between the cells C2 are determined by the fabrication process and in particular by the patterning steps.

Of note, in some embodiments described above in connection with FIGS. 1-7, an amorphous silicon solar cell capable of absorbing the short wavelengths and a compound solar cell capable of absorbing the long wavelengths are manufactured separately as two separate module layers, and then are bonded together by the EVA sheet 170 to form a highly efficient stacked-type solar cell module with different materials. In contrast, in a conventional stacked type solar cell, the constituent module layers (such as layers B and T) do not exist separately prior to bonding; consequently, if one of the module layers is defective, the whole solar cell module is unusable. Advantageously, in FIGS. 2-7, the bottom module layer B and the top module layer T are manufactured independently, making it possible to increase the manufacturing yield.

We turn now to possible interconnection and voltage matching for solar cell modules such as described above.

FIG. 8 is a perspective view showing the solar cell module having the multiple module layers connected according to some embodiments of the present invention. In the solar cell module of FIG. 8, the bottom module layer B and the top module layer T are separately manufactured and are bonded together by means of the EVA sheet 170. More particularly, the EVA sheet 170 bonds the reflecting filter 160 of the bottom module layer B to the second transparent conductive film of the top module layer T.

The positive and negative output electrodes of the bottom module layer B are connected to respective output signal lines S1. The positive and negative output electrodes of the top module layer T are connected to respective output signal lines S2. Even though the bottom module layer B and the top module layer T are bonded together, the output signal lines S1 and the output signal lines S2 may be used independently of each other for connection to external devices. Therefore, the bottom module layer B and the top module layer T can each supply power to external devices independently of each other.

FIG. 9 is a perspective view showing solar cell module connection according to another embodiment of the present invention. As shown in FIG. 9, the bottom module layer B and the top module layer T (which are bonded together by means of the EVA sheet 170) may be connected to each other in parallel. The bottom module layer B and the top module layer T may output different voltages. If the output voltages are different, loss of electric energy may occur in the parallel connection. Therefore, the output voltages of the bottom module layer B and the top module layer T should preferably be equalized. This can be achieved by appropriately choosing the number of cells C1 and C2 when the bottom module layer B and the top module layer T are manufactured.

More particularly, the final output voltage VT1 of the bottom module layer B is as follows:

VT1=N1*V1

where N1 represents the number of serially connected cells C1 in the bottom module layer B and V1 represents the output voltage of each unit cell C1.

Likewise, the final output voltage VT2 of the top module layer T is as follows:

VT2=N2*V2

where N2 represents the number of serially connected cells C2 in the top module layer T and V2 represents the output voltage of each unit cell C2.

In some embodiments using the parallel interconnection of FIG. 9, the cell numbers N1, N2 of the respective serially interconnected chains of cells C1, C2 are chosen to satisfy the following condition:

0.6≦(N1/N2)≦0.8 (1)

The number of cells C1 and C2 can be set by defining the patterning steps for the manufacturing process to satisfy the condition (1). Consequently, the output voltages generated by the bottom module layer B and the top module layer T can be made equal (or approximately equal) to each other.

The output signal lines S1, S2 can be connected to the load (i.e. to the external devices) via Schottky diodes to prevent reverse current flow that might be generated due to minute differences between the output voltages of the bottom module layer B and the top module layer T. FIG. 9 shows two Schottky diodes D connected respectively to the output signal lines S1, S2 at the positive output electrodes of the bottom module layer B and the top module layer T.

A compound solar cell (CIGS) is a high efficiency solar cell that converts sunlight into electricity without using silicon. The CIGS cell may be manufactured by depositing a compound of copper, indium, gallium, and selenium on a glass substrate or a flexible substrate such as stainless steel, aluminum, and the like.

The photoelectric conversion efficiency of the CIGS solar cell is about 12%. Although the CIGS solar cell is inferior to the crystalline silicon solar cell with regard to the photoelectric conversion efficiency, the CIGS cell can be manufactured with a much simper and less expensive fabrication process than the crystalline silicon solar cell.

The amorphous silicon solar cell has its own disadvantages. In particular, the amorphous silicon solar mainly absorbs the short wavelengths of 730 nm and below and generates a small current despite the cell's high open circuit voltage. Since the CIGS solar cell can absorb sunlight in the wavelength band of 730 nm to 1000 nm inclusive, the CIGS cell can provide high current despite the cell's low open circuit voltage.

The solar cell module having a plurality of cell layers can combine the merits of the amorphous silicon solar cell and the compound solar cell. Since the amorphous silicon solar cell and the compound solar cell are manufactured by different processes due to the cells' use of different materials, it is difficult to manufacture a solar cell module by sequentially stacking the multiple layers forming the amorphous silicon solar cell and the compound solar cell. Also, if the module is manufactured by such sequential stacking, the defect probability may double.

In some embodiments of the present invention, the foregoing problems can be prevented by separate fabrication of the amorphous silicon solar cell and the compound solar cell. The cells (i.e. the cell layers) are bonded together after each cell layer has been fabricated. The proper voltage matching can be achieved by controlling the number of cells of each layer to provide high efficiency.

The embodiments described above illustrate but do not limit the invention. Other embodiments and variations are within the scope of the invention, as defined by the appended claims.

What is claimed is:

1. A solar cell module comprising:
a first substrate;
a bottom module layer formed on the first substrate and absorbing a greater fraction of light energy in a first wavelength band than in a second wavelength band, the first wavelength band comprising a shorter wavelength than any wavelength in the second wavelength band;
a top module layer formed on the bottom module layer and absorbing a greater fraction of light energy in the second wavelength band than in the first wavelength band;
a second substrate formed on the top module layer; and
a reflecting filter between the bottom module layer and the top module layer,
wherein the bottom module layer and the top module layer are bonded to each other by a polyethylene vinyl acetate (EVA) sheet disposed between the bottom module layer and the top module layer,
wherein the reflecting filter reflects a greater fraction of light energy in the first wavelength band than in the second wavelength band and transmitting a greater fraction of light energy in the second wavelength band than in the first wavelength band
wherein the bottom module layer and the top module layer each include a plurality of unit cells that are serially connected to each other.

2. The solar cell module of claim 1 wherein:
(1) the bottom module layer comprises:
a first transparent conductive film formed on the first substrate;
a first semiconductor layer comprising: (i) a first P layer disposed on the first transparent conductive film, (ii) an I layer formed of intrinsic amorphous silicon and disposed on the first P layer, and (iii) a first N layer disposed on the first P layer; and
a transparent electrode disposed on the first semiconductor layer; and
(2) the top module layer comprises:
a reflecting electrode film disposed on the second substrate;
a second semiconductor layer comprising: (i) a second P layer disposed on the reflecting electrode film, and (ii) a second N layer disposed on the second P layer; and
a second transparent conductive film disposed on the second semiconductor layer,
wherein the polyethylene vinyl acetate (EVA) sheet is disposed between the transparent electrode and the second transparent conductive film.

3. The solar cell module of claim 2, wherein
the second P layer is formed of CuInSe₂ (CIS) or CuInGaSe₂ (CIGS), and the second N layer is formed of CdS.

4. The solar cell module of claim 3, wherein
the reflecting electrode film is formed of one of aluminum (Al), copper (Cu), and molybdenum (Mo).

5. The solar cell module of claim 4, wherein
the transparent electrode is formed of one of SnO₂, ZnO:Al, and ZnO:B.

6. The solar cell module of claim 1, wherein the reflecting filter is formed of a material based on an inorganic oxide film.

7. The solar cell module of claim 1, wherein the reflecting filter is formed of TiO₂ or SiNx.

8. The solar cell module of claim 1, wherein
the bottom module layer and the top module layer each include output electrodes that are connected to one or more external devices, the output electrodes of the top module layer not being directly connected to the output electrodes of the bottom module layer.

9. The solar cell module of claim 1, wherein
the bottom module layer is connected in parallel to the top module layer, and:
0.6≦(N1/N2)≦0.8
where N1 is the number of cells that are serially connected to each other in the bottom module layer and N2 is the number of cells that are serially connected to each other in the top module layer.

10. The solar cell module of claim 9, further comprising a Schottky diode connected between an output electrode of the bottom module layer at least one external device, and comprising a Schottky diode connected between an output electrode of the top module layer at least one external device.

11. A method for manufacturing a solar cell module comprising a bottom module layer for absorbing a greater fraction of light energy in a first wavelength band than in a second wavelength band, the first wavelength band comprising a shorter wavelength than any wavelength in the second wavelength band, the solar cell module also comprising a top module layer formed on the bottom module layer and absorbing a greater fraction of light energy in the second wavelength band than in the first wavelength band, the method comprising:
forming the bottom module layer on a first substrate, the bottom module layer comprising a plurality of cells serially connected to each other;
forming a reflecting filter over the bottom module layer, the reflecting filter reflecting a greater fraction of light energy in the first wavelength band than in the second wavelength band and transmitting a greater fraction of light energy in the second wavelength band than in the first wavelength band;
forming the top module layer on a second substrate, the top module layer comprising a plurality of cells serially connected to each other; and
after forming the bottom module layer and the top module layer, bonding the bottom module layer and the top module layer together by using an EVA sheet.

12. The method of claim 11, wherein forming the bottom module layer comprises:
depositing a first transparent conductive film on the first substrate;
patterning the first transparent conductive film;
after patterning the first transparent conductive film, forming a first semiconductor layer over the first transparent conductive film, the first semiconductor layer comprising a first P layer, an I layer of amorphous silicon overlying the first P layer, and a first N layer overlying the I layer;
patterning the first semiconductor layer;
after patterning the first semiconductor layer, forming a transparent electrode over the first semiconductor layer; and
after forming the transparent electrode, patterning the transparent electrode and the first semiconductor layer.

13. The method of claim 12, wherein the transparent electrode is formed of one of SnO₂, ZnO:Al, and ZnO:B.

14. The method of claim 13, further comprising texturing an upper surface of the first transparent conductive film.

15. The method of claim 12, wherein forming the top module layer comprises:
forming a reflecting electrode film on the second substrate;
patterning the reflecting electrode film;
after patterning the reflecting electrode film, forming a second semiconductor layer over the reflecting electrode film, the second semiconductor layer comprising a stack of a second P layer formed of CuInSe₂ or CuInGaSe (CIGS) and a second N layer;
patterning the second semiconductor layer;
after patterning the second semiconductor layer, forming a second transparent conductive film over the second semiconductor layer; and then
patterning the second transparent conductive film and the second semiconductor layer.

16. The method of claim 15, wherein the second P layer has a bandgap of 1.2 eV to 1.45 eV.

17. The method of claim 15, further comprising texturing the upper surface of the reflecting electrode film after forming the reflecting electrode film.

18. The method of claim 11, further comprising connecting output electrodes of each of the bottom module layer and the top module layer to one or more external devices, the output electrodes of the top module layer not being directly connected to the output electrodes of the bottom module layer.

19. The method of claim 11, further comprising connecting the bottom module layer and the top module layer to each other in parallel, wherein:
0.6≦(N1/N2)≦0.8
wherein N1 is the number of cells that are serially connected to each other in the bottom module layer and N2 is the number of cells that are serially connected to each other in the top module layer.

20. The method of claim 19, further comprising connecting a Schottky diode between an output electrode of the bottom module layer and at least one external device, and connecting a Schottky diode between an output electrode of the top module layer and at least one external device.

21. The method of claim 11, wherein the reflecting filter comprises an inorganic oxide film.

22. The method of claim 11, wherein the reflecting filter is formed of TiO₂ or SiNx.
